(19) United States
(12) Patent Application Publication
(10) Pub. No.: US 2015/0357546 A1
(43) Pub. Date: Dec. 10, 2015

(54) Thermoelectric Module And Device, In Particular Designed To Generate An Electric Current In A Motor Vehicle

(71) Applicants: Michel SIMONIN, Voisins le Bretonneux (FR); VALEO SYSTEMES THERMIQUES, Le Mesnil Saint Denis (FR)

(72) Inventor: Michel SIMONIN, Voisins le Bretonneux (FR)

(21) Appl. No.: 14/655,483

(22) PCT Filed: Dec. 20, 2013
(86) PCT No.: PCT/EP2013/077833

§ 371 Date: Jun. 25, 2015

(30) Foreign Application Priority Data
Dec. 28, 2012 (FR) 1262921

(51) Int. Cl. H01L 35/32; H01L 35/30

(52) U.S. Cl. CPC H01L 35/32; H01L 35/30

(57) ABSTRACT

The invention relates to a thermoelectric module comprising at least one annular thermoelectric element (3, 3p, 3n), capable of generating an electric current under the action of a temperature gradient exerted between two of its faces, one (4a), called the first face, being defined by an outer peripheral surface and the other (4b), called the second face, being defined by an inner peripheral surface, said module being configured to establish a heat exchange between said first face (4a) and a first fluid and to establish a heat exchange between said second face (4b) and a second fluid, such that said first fluid and said second fluid circulate transversely relative to one another. The invention also relates to a thermoelectric device comprising a plurality of such modules.

The present invention relates to a thermoelectric module and device, in particular designed to generate an electric current in a motor vehicle.

In the automotive field, thermoelectric devices using elements referred to as thermoelectric elements have already been proposed, making it possible to generate an electric current when a temperature gradient is present between two of their opposite faces in accordance with a phenomenon known as the Seebeck effect. These devices comprise a stack of first tubes, intended for the circulation of the exhaust gases from an engine, and of second tubes, intended for the circulation of a heat-transfer fluid of a cooling circuit. The thermoelectric elements are sandwiched between the tubes so as to be subjected to a temperature gradient arising from the difference in temperature between the hot exhaust gases and the cold cooling fluid.

Such devices are particularly advantageous since they make it possible to produce electricity from a conversion of the heat coming from the exhaust gases of the engine. They thus offer the possibility of reducing the fuel consumption of the vehicle, by being substituted, at least in part, for the alternator normally provided in said vehicle to generate electricity using a belt driven by the engine crankshaft.

The proprietor has already developed annular-shaped thermoelectric elements, the temperature gradient for generating the expected electric current being imposed between two of their opposite cylindrical faces. The hot fluid and the cold fluid then circulate coaxially, one circulating inside the ring and the other outside. This solution does, however, present difficulties in integration that give rise to the involvement of a large quantity of material. Apart from the consequences on the cost price, such an involvement of material increases the thermal inertia of the device and therefore its efficiency, in particular its response time. It may thus not be capable of profiting from high but excessively short increases in heat.

The invention sets out to improve the situation and to this end relates to a thermoelectric module comprising at least one annular-shaped thermoelectric element, capable of generating an electric current under the action of a temperature gradient exerted between two of its faces, one, referred to as the first face, being defined by an outer peripheral surface, in particular cylindrical, and the other, referred to as the second face, being defined by an inner peripheral surface, in particular cylindrical, said module being configured so as to establish a heat exchange between said first face and a first fluid and to establish a heat exchange between said second face and a second fluid, so that said first fluid and said second fluid circulate transversely, in particular perpendicularly, relative to each other.

By virtue of the transverse orientation of the circulation of fluid, it is possible to limit the material involved, in particular on the first-fluid side, therefore increasing the heat-exchange surfaces. Such a configuration furthermore gives greater possibilities for positioning the various manifolds intended to be connected to the module in order to supply it with fluid, and thus facilitates its integration in its environment.

According to one embodiment of the invention, the thermoelectric module is arranged so as to guide the first fluid transversely to the second fluid.

According to one aspect of the invention, said thermoelectric module is configured to allow a circulation of said first and second fluids, said second fluid having a heat-exchange coefficient greater than said first fluid. The first fluid is in particular exhaust gas. The second fluid is, for example, a cooling liquid.

The invention thus proposes a module, the efficiency of which is optimised by the fact that the heat-exchange surface is larger with regard to the fluid having the lowest heat-exchange coefficient. In this way, there is a more balanced ratio between the thermal resistance on the first-fluid side, for example gas, and the thermal resistance on the second-fluid side, in particular liquid, enhancing the functioning of the whole.

According to one aspect of the invention, the cylinder formed by said thermoelectric elements is made thinner in the direction of circulation of the first fluid so that it offers less resistance to the first fluid. The cylinder has in particular a base with a substantially oval shape. The thinner external form of the thermoelectric elements makes it possible in particular to reduce the main aerodynamic torque of the thermoelectric element and therefore to reduce the resistance to the flow of the gases, for the same overall dimensions.

Advantageously, said thermoelectric element has two opposite parallel flat faces.

According to one embodiment of the invention, the module comprises a plurality of said thermoelectric elements. Said thermoelectric elements can be arranged with respect to one another so that their first and/or second surfaces are in line with one another.

According to one aspect of the invention, said thermoelectric elements are of two different types. Advantageously, said thermoelectric elements are here of a first type, referred to as the P-type, for establishing a difference in electrical potential between said first and second faces, when they are subjected to a given temperature gradient, and of a second type, referred to as the N-type, for creating a difference in electrical potential in an opposite direction between said first and second faces when they are subjected to the same temperature gradient.

At least two thermoelectric elements of the same type can alternate in a direction of longitudinal extension of the module with a thermoelectric element of the other type. Advantageously, said thermoelectric elements are arranged longitudinally in line with one another and the P-type thermoelectric elements alternate with the N-type thermoelectric elements.

According to one aspect of the invention, the thermoelectric elements are grouped in pairs, formed by a said P-type thermoelectric element and a said N-type thermoelectric element, said module being configured so as to allow a flow of current between the first surfaces of the thermoelectric elements in the same pair and a flow of current between the second surfaces of each of the thermoelectric elements in said same pair and the adjacent thermoelectric element in the adjacent pair.

According to one aspect of the invention, said thermoelectric elements have identical shapes and dimensions. In other words, they have an identical inner periphery, outer periphery and thickness, that is to say a dimension along their longitudinal axis.

In a variant, their thickness may be different, in particular according to their electrical conductivity. More precisely, the N-type thermoelectric elements may be more electrically conductive than the P-type thermoelectric elements, and the thickness of said N-type thermoelectric elements will be less than the thickness of the P-type thermoelectric elements, or vice versa. Thus the electrical resistances of the thermoelectric elements of each of the types of thermoelectric elements may be more balanced, with a lesser thickness of N-type thermoelectric elements, or conversely of P-type thermoelectric elements, therefore saving on material.

According to one aspect of the invention, the module comprises first electrical connection means connecting the outer peripheral surfaces of two of said thermoelectric elements, provided so as to be adjacent and of different types, said secondary heat-exchange surfaces being fixed to said first electrical connection means. The secondary exchange surfaces are, for example, crimped to the first electrical connection means. In another embodiment, they are brazed to said first electrical connection means, in particular by means of electrically conductive brazing.

Advantageously, the secondary heat-exchange surfaces have said thermoelectric elements passing through them.

Advantageously, the secondary heat-exchange surfaces lie in planes parallel to the direction of circulation of the first fluid.

According to one embodiment of the invention, the secondary heat-exchange surfaces are fins. They are in particular made from metal.

According to one aspect of the invention, the secondary heat-exchange surfaces comprise a catalytic coating for providing a catalytic conversion of toxic components of the first fluid.

According to one aspect of the invention, the module comprises second electrical connection means establishing an electrical connection between the inner peripheral surfaces of two of said thermoelectric elements, provided so as to be adjacent, of different types and not connected by said first electrical connection means.

Advantageously, said module further comprises electrical insulation means arranged between two adjacent thermoelectric elements, of different types, said electrical insulation means being configured so as to electrically insulate from one another lateral faces of the thermoelectric elements connected by said first and/or second electrical connection means and/or to electrically insulate from one another the secondary heat-exchange surfaces connected to two of said thermoelectric elements, connected by the second electrical connection means. Thus, the invention limits the risk of a short circuit being created between the secondary heat-exchange surfaces.

According to one aspect of the invention, the module comprises a channel for circulation of the second fluid in contact with said second surface of said thermoelectric elements.

Advantageously, the channel extends along an axis that is off-centre with respect to a central axis of the cylinder formed by said thermoelectric elements.

According to one aspect of the invention, the off-centre axis of the channel is situated in a plane defined by the central axis of the cylinder and the direction of circulation of the first fluid. By orientating the thermoelectric elements with respect to the direction of circulation of the first fluid, concentric electrical equipotential regions are in this way arranged inside the thermoelectric elements.

In a variant, the module can also comprise a plurality of cold-liquid circulation channels, in particular parallel to one another, each channel cooperating with a plurality of thermoelectric elements each forming an angular section of a cylinder and positioned in line with one another in the direction of longitudinal extension of the corresponding channel.

The invention also relates to a thermoelectric device comprising a plurality of modules as described above.

According to one embodiment of the invention, said secondary heat-exchange surfaces connect the modules together so that they have said modules passing through them.

According to one aspect of the invention, said device is configured so as to allow a flow of the first fluid in a direction transverse to a direction of circulation of the second fluid through said modules.

According to one embodiment of the invention, the device comprises a duct for guiding the first fluid in a direction of circulation of the first fluid, said modules being arranged transversely to said direction of circulation of the first fluid.

Advantageously, said device is configured so as to be positioned in a motor vehicle exhaust gas pipe so that said secondary heat-exchange surfaces are swept by said gases, said gases defining said first fluid. The exhaust gas pipe is in particular said duct for guiding the first fluid.

The invention will be better understood in the light of the following description, which is given only by way of indication and is not intended to limit it, together with the accompanying drawings, in which:

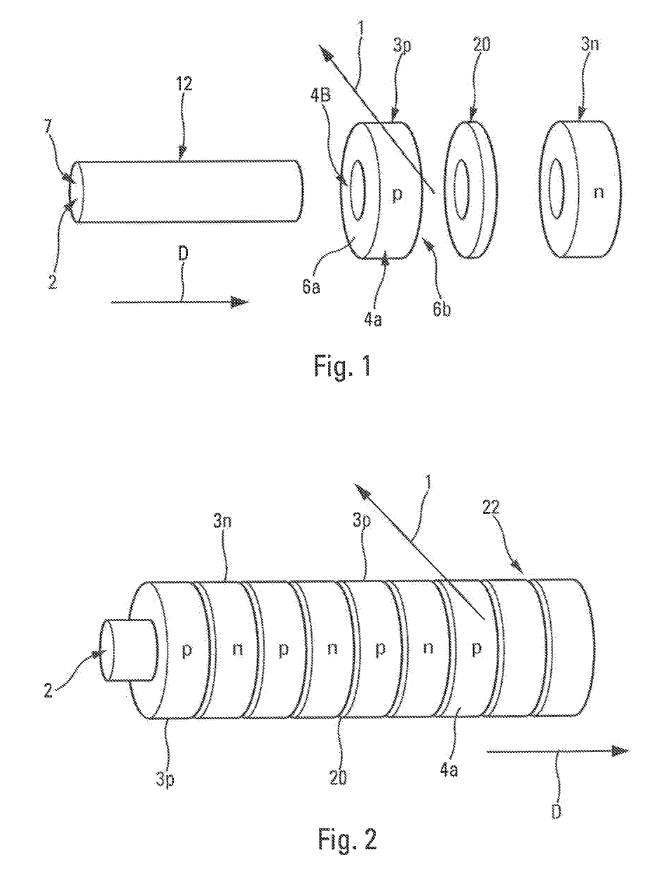

FIGS. 1 and 2 show schematically, in perspective, steps for assembling an example of a module according to the invention;

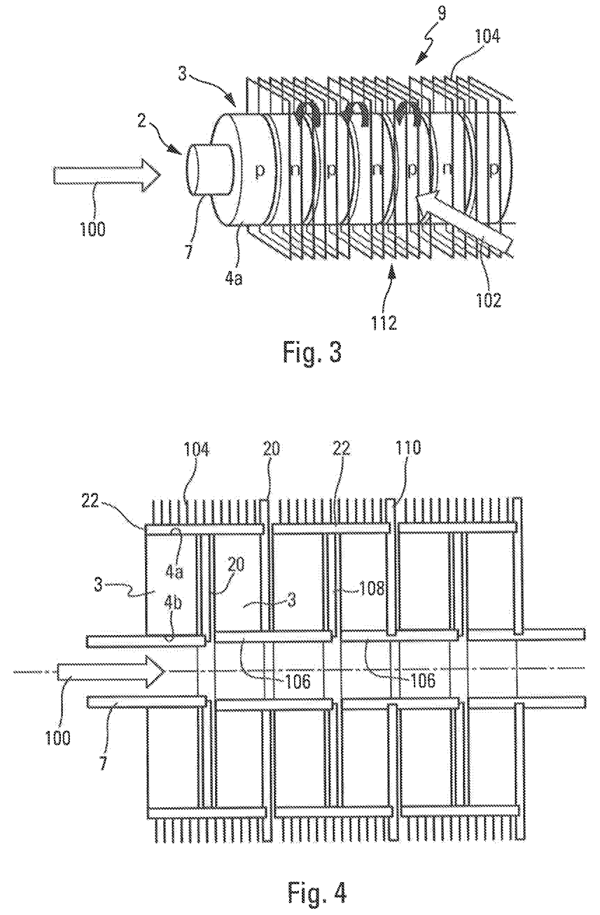

FIG. 3 shows schematically, in perspective, an example of a module according to the invention;

FIG. 4 shows schematically, along a longitudinal cutting plane, the module of FIG. 3;

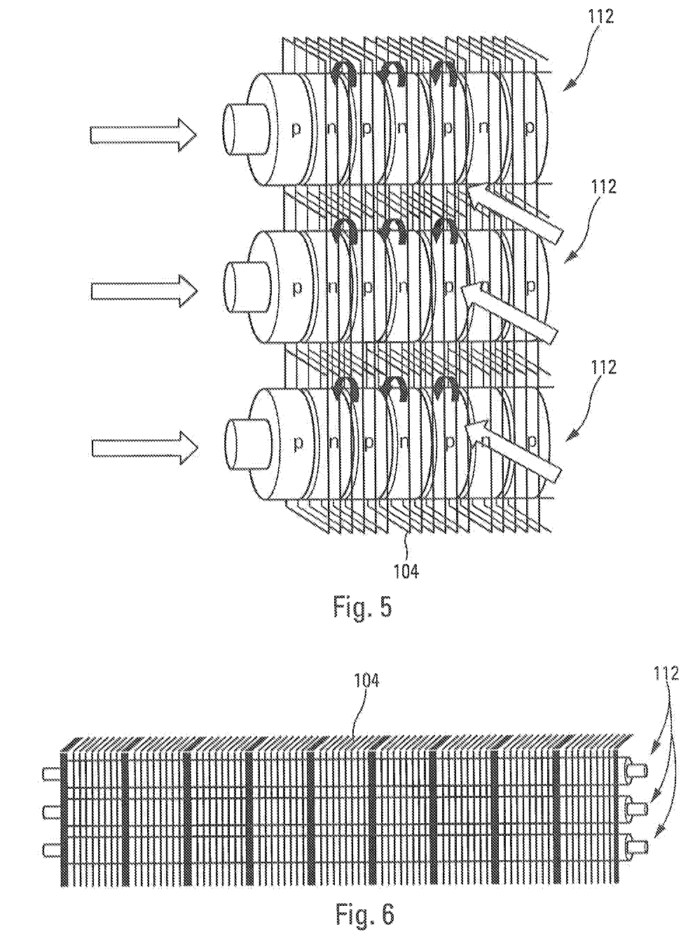

FIG. 5 shows schematically, in perspective, an example of a device according to the invention comprising a plurality of modules;

FIG. 6 shows schematically, in perspective, another embodiment of the device shown in FIG. 5;

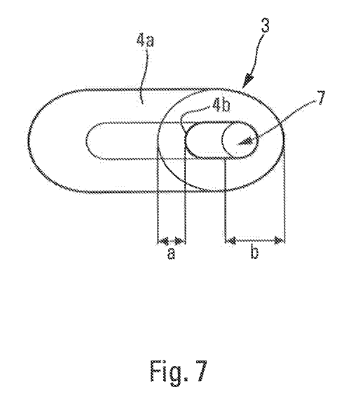

FIG. 7 shows schematically, in perspective, a particularity of an embodiment of the module according to the invention.

As shown in FIGS. 1 and 2, the invention relates to a thermoelectric module. Said module comprises here a first so-called hot circuit 1, capable of allowing the circulation of a first fluid, in particular exhaust gases from an engine, and a second so-called cold circuit 2, capable of allowing the circulation of a second fluid, in particular a heat-transfer fluid of a cooling circuit, with a temperature less than that of the first fluid.

Said second fluid thus has a heat-exchange coefficient higher than said first fluid.

The module comprises at least one thermoelectric element, here a plurality of thermoelectric elements 3p, 3n, annular in shape, able to generate an electric current under the action of a temperature gradient exerted between two of its faces, one 4a, referred to as the first face, being defined by an outer cylindrical peripheral surface, and the other 4b, referred to as the second face, being defined by an inner cylindrical peripheral surface. As will be elaborated below, said first and second faces 4a, 4b have, for example, oval cross sections in the first case and/or circular cross sections in the second case. More generally, any rounded and/or polygonal cross section is possible.

Such elements function, according to the Seebeck effect, by allowing an electric current to be created in a load connected between said faces 4a, 4b subjected to the temperature gradient. As is known to persons skilled in the art, such elements are formed, for example, from bismuth and tellurium (Bi₂Te₃).

The thermoelectric elements may firstly be elements 3p of a first type, referred to as the P-type, for establishing a difference in electrical potential in a so-called positive direction when they are subjected to a given temperature gradient and the rest of them may be elements 3n of a second type, referred to as the N-type, for creating a difference in electrical potential in an opposite, so-called negative direction when they are subjected to the same temperature gradient.

In FIGS. 1 and 2, the thermoelectric elements 3 depicted consist of a ring in a single piece. They may, however, be formed from a plurality of pieces each forming an angular portion of the ring.

The first surface 4a has, for example, a radius of between 1.5 and 4 times the radius of the second surface 4b. It may be a radius equal to approximately twice that of the second surface 4b.

Said thermoelectric element has, for example, two opposite parallel flat faces 6a, 6b. In other words, the ring constituting the thermoelectric element has a rectangular annular cross section.

Hereinafter, an example of the association of the thermoelectric elements with one another in the module according to the invention is described.

Said thermoelectric elements 3p, 3n are arranged, for example, longitudinally in line with one another, in particular coaxially, and the P-type thermoelectric elements alternate with the N-type thermoelectric elements, in a direction D. They have in particular identical shapes and dimensions. They may, however, have a thickness, that is to say a dimension between their two flat faces, that is different from one type to the other, in particular according to their electrical conductivity.

Said thermoelectric elements 3p, 3n are, for example, grouped in pairs, each pair being formed by a said P-type thermoelectric element and a said N-type thermoelectric element, and said module being configured so as to allow a flow of current between the first surfaces of the thermoelectric elements in the same pair and a flow of current between the second surfaces of each of the thermoelectric elements in said same pair and the adjacent thermoelectric element in the adjacent pair. In this way, a flow in series of the electric current between the thermoelectric elements 3p, 3n which are arranged alongside one another in the direction D is provided.

Once again in order to facilitate the configuration of the fluid-circulation circuits 1, 2, provision can be made for said thermoelectric elements 3p, 3n to be arranged with respect to one another so that their first and/or second surfaces 4a, 4b are in line with one other. Said first and/or second surfaces 4a, 4b thus, for example, fit in a surface generated by a straight line.

For the circulation of the fluids, the module according to the invention may comprise a cold-liquid circulation channel 7 in contact with said second surface 4b of said thermoelectric elements 3p, 3n.

Said liquid circulation channel or channels 7 have, for example, a circular cross section.

In FIG. 1, it can be seen that said module comprises cold-liquid circulation tubes 12 on which at least two thermoelectric elements of the same type are mounted, alternating in the longitudinal extension direction D of the tube with a thermoelectric element of the other type. The tubes 12 are in particular metal. They at least partly define said channel 7.

Said module may further comprise electrical insulation means 20 arranged between two opposite faces 6a, 6b of adjacent thermoelectric elements 3p, 3n in the direction D of longitudinal extension of the tube 12. In FIG. 2, the thermoelectric elements 3p, 3n and the electrical insulation means 20 are assembled in alternation on the cold-fluid circulation tubes 12.

Said module may also comprise first electrical connection means 22 connecting the outer peripheral surfaces 4a of two of said thermoelectric elements, provided so as to be adjacent and of different types. Said first electrical connection means 22 comprise, for example, a layer of electrically conductive material, in particular made from copper and/or nickel, which clads said thermoelectric elements 3p, 3n.

According to the above, the cold-liquid circulation channel 7 is the only one and is placed at the centre of the module. According to a variant, a plurality of cold-liquid circulation channels may be provided.

That being the case, as shown in FIG. 3, said module is configured so as to establish a heat exchange between said first face 4a and the first fluid, circulating here in the channel 7 in the direction of the arrow denoted by 100, and to establish a heat exchange between said second face 4b and the second fluid, circulating here outside said thermoelectric elements 3 in the direction of the arrow denoted by 102. In this way, exchange between the thermoelectric elements 3 and the fluid having the lowest heat-exchange coefficient, in this case the exhaust gases, is promoted.

According to the invention, said module is further configured so that said first fluid and said second fluid circulate transversely, in particular orthogonally, with respect to each other, as shown by the orientation of the arrows 100, 102. Such a configuration favours the integration of the module in its environment by moreover reducing the quantities of material involved. The thermoelectric module of the invention is therefore arranged so as to guide the first fluid transversely to the second fluid.

Said module advantageously comprises surfaces 9, in particular fins 104, for secondary heat exchange with the first fluid. In this way, the heat-exchange surface between the thermoelectric elements 3 and said first fluid is increased. Said fins 104 are arranged, for example, transversely, in particular radially, to said thermoelectric elements 3. They are here positioned parallel to one another with a separation affording a good exchange of heat with the first fluid while limiting head losses. Said fins 104 may be off-centre with respect to said thermoelectric elements 3p, 3, in particular elongated on the side where the first fluid arrives.

Said secondary heat-exchange surfaces 9 may comprise a catalytic coating for providing a catalytic conversion of toxic components of the first fluid. In the case of exhaust gases, said module may in this way equip a catalytic converter in addition to or in substitution for the components conventionally used for catalysis in such items of equipment.

As shown in FIG. 4, said fins 104 are fixed, for example, to said first electrical connection means 22, in particular by crimping and/or brazing.

The module may further comprise second electrical connection means 106 establishing an electrical connection between the inner peripheral surfaces 4b of two of said thermoelectric elements 3, provided so as to be adjacent, of different types and not connected by said first electrical connection means 22.

In other words, said first and second electrical connection means 22, 106 connect said thermoelectric elements 3 in pairs so as to establish an electrical circulation in series between said thermoelectric elements of the module.

As already mentioned, the module according to the invention advantageously comprises electrical insulation means 20 arranged between two adjacent thermoelectric elements 3. Said electrical insulation means are of two types. A first type 108 is configured so as to electrically insulate from one another the lateral faces of the thermoelectric elements connected by said first electrical connection means 22. A second type 110 is configured so as to electrically insulate from one another the lateral faces of the thermoelectric elements connected by said second electrical connection means 106 and/or to electrically insulate from one another the fins 104 connected to two of said thermoelectric elements, connected by the second electrical connection means 106.

Such a configuration limits the risks of short circuits between the thermoelectric elements 3 that might occur by means of said fins 106.

As shown in FIG. 7, said channel 7 may extend along an axis that is off-centre with respect to a central axis of a cylinder formed by said thermoelectric elements 3, depicted here in a single block for reasons of simplification. Said off-centre axis of the channel is situated, for example, in a plane defined by the central axis of the cylinder and the direction of circulation of the first fluid. In this way, by varying the thickness of the thermoelectric elements 3 around the channel 7, better distribution of the current equipotentials in the thermoelectric elements 3 is obtained.

Alternatively or cumulatively, said cylinder is made thinner in the direction of circulation of the first fluid so that it offers less resistance to the first fluid. This being the case, in a variant, said first and/or second surfaces 4a, 4b may be coaxial. In other words, the thermoelectric element is provided with a constant radial thickness.

As shown in FIGS. 5 and 6, the invention also relates to a device comprising a plurality of modules as described above, here in the form of pencils 112 stacked alongside one another and/or above one another.

From an electrical point of view, the modules may be connected together in series and/or in parallel, by connections, not shown, situated at their longitudinal ends.

Said fins 104 connect the modules together so that they have said modules passing through them.

As already mentioned, such a device may be configured so as to be positioned in a motor vehicle exhaust gas pipe so that said secondary heat-exchange surfaces are swept by said gases. In other words, the gases are intended to be channeled across the fins by the exhaust gas pipe itself, whereas the second fluid can be circulated by inlet/outlet manifolds positioned laterally, giving rise to great simplicity of integration.

The device thus comprises a duct for guiding the first fluid, here the exhaust gas pipe, for guiding the first fluid transversely to the modules, that is to say transversely to the longitudinal direction defined by the pencil shapes of the modules. In other words, the modules are arranged transversely to said direction of circulation of the first fluid. It will be understood here that said device is configured so as to allow a flow of the first fluid in a direction transverse to a direction of circulation of the second fluid through said modules.

The guide duct is therefore transverse to the channels 7 of circulation of the second fluid.

The device may also comprise modules arranged one after the other in the direction of circulation of the first fluid, that is to say here following one another in the guide duct.

In general terms, it will be understood that the invention, by circulating hot fluid outside the thermoelectric elements and transversely to the circulation of cold fluid, optimises the heat-exchange surfaces in contact with said thermoelectric elements, promoting the obtaining of high temperatures at the external surface of said thermoelectric elements. It also assists the installation of the equipped devices.

It may also be noted that, by virtue in particular of the insulation means installed, said device generates no current or short circuit when the engine stops or starts.

1. A thermoelectric module comprising at least one annular-shaped thermoelectric element (3, 3p, 3n) capable of generating an electric current under the action of a temperature gradient exerted between two of its faces, one (4a), referred to as the first face, being defined by an outer peripheral surface, and the other (4b), referred to as the second face, being defined by an inner peripheral surface, the module being configured so as to establish a heat exchange between the first face (4a) and a first fluid, and to establish a heat exchange between the second face (4b) and a second fluid, so that the first fluid and the second fluid circulate transversely relative to each other.

2. A module according to claim 1, wherein a cylinder which is formed by the thermoelectric elements (3, 3p, 3n) is made thinner in the direction of circulation of the first fluid so that it offers less resistance to the first fluid.

3. A module according to claim 2, further comprising a plurality of the thermoelectric elements (3, 3p, 3n) of two different types.

4. A module according to claim 3, wherein at least two thermoelectric elements (3, 3p, 3n) of the same type alternate in a direction of longitudinal extension of the module with a thermoelectric element of the other type.

5. A module according to claim 3, further comprising surfaces (9) for secondary heat exchange with the first fluid.

6. A module according to claim 5, further comprising first electrical connection means (22) connecting the outer peripheral surfaces of two of the thermoelectric elements (3, 3p, 3n), provided so as to be adjacent and of different types, the secondary heat exchange surfaces (9) being fixed to the first electrical connection means (22).

7. A module according to claim 6, wherein the secondary heat exchange surfaces (9) are fins.

8. A module according to claim 5, wherein the secondary heat exchange surfaces (9) comprise a catalytic coating for providing a catalytic conversion of toxic components of the first fluid.

9. A module according to claim 5, further comprising second electrical connection means (106) establishing an electrical connection between the inner peripheral surfaces of two of the thermoelectric elements (3, 3p, 3n), provided so as to be adjacent, of different types and not connected by the first electrical connection means (22), and electrical insulation means (20) arranged between two adjacent thermoelectric elements (3, 3p, 3n) of different types, the electrical insulation means (20) being configured so as to electrically insulate from one another lateral faces of the thermoelectric elements (3, 3p, 3n) connected by the first (22) and/or second electrical connection means (106) and/or to electrically insulate from one another the secondary heat exchange surfaces (9) connected to two of the thermoelectric elements (3, 3p, 3n) connected by the second electrical connection means (106).

10. A module according to claim 5, further comprising a channel (7) for circulation of the second fluid in contact with the second surface (4b) of the thermoelectric elements (3, 3p, 3n).

11. A module according to claim 10, wherein the channel (7) extends along an axis that is off-centre with respect to a central axis of the cylinder formed by the thermoelectric elements (3, 3p, 3n).

12. A module according to claim 11, wherein the off-centre axis of the channel (7) is situated in a plane defined by the central axis of the cylinder and the direction of circulation of the first fluid.

13. A thermoelectric device comprising a plurality of modules according to claim 5.

14. A thermoelectric device according to claim 13, wherein the secondary heat exchange surfaces (9) connect the modules together so that the modules pass through them.

15. A thermoelectric device according to claim 13, wherein the device is configured so as to allow a flow of the first fluid in a direction transverse to a direction of circulation of the second fluid through the modules.

16. A thermoelectric device according to claim 15, wherein the device comprises a duct for guiding the first fluid in a direction of circulation of the first fluid, the modules being arranged transversely to the direction of circulation of the first fluid.

17. A thermoelectric device according to claim 13, configured so as to be positioned in a motor vehicle exhaust gas pipe so that the secondary heat exchange surfaces (9) are swept by gases, the gases defining the first fluid.
